(19) United States
(12) Patent Application Publication
(10) Pub. No.: US 2022/0224274 A1
(43) Pub. Date: Jul. 14, 2022

(54) APPARATUS AND METHOD FOR PROVIDING AT LEAST ONE DRIVE SIGNAL

(71) Applicant: Dunkermotoren GmbH, Bonndorf / Schwarzwald (DE)

(72) Inventor: Johannes Flügel, Weilheim (DE)

(21) Appl. No.: 17/571,390

(22) Filed: Jan. 7, 2022

(30) Foreign Application Priority Data
Jan. 13, 2021 (DE) 102021100555.8

(51) Int. Cl. H02P 29/00; H03K 19/20

(52) U.S. Cl. CPC H02P 29/00; H03K 19/20

(57) ABSTRACT

Apparatus for providing at least one drive signal for an electrical load, comprising: an enabling device adapted to receive at least one input signal and, based on the at least one input signal, to output, for example at least temporarily, the at least one drive signal, wherein the apparatus further comprises an activating device adapted to selectively activate or deactivate the enabling device.

### CROSS REFERENCE TO RELATED APPLICATIONS

The present application claims priority under 35 U.S.C. § 119(a) to German National Patent Application No. DE 10 2021 100 555.8 filed on Jan. 12, 2021 and entitled, “Apparatus and Method for Providing at least one Drive Signal,” which is hereby expressly incorporated by reference herein.

### FIELD

The disclosure relates to a device and method for providing at least one drive signal, for example for an electrical load.

### SUMMARY

Exemplary embodiments relate to an apparatus for providing at least one drive signal for an electrical load, comprising: an enabling device adapted to receive at least one input signal and, based on the at least one input signal, to output, for example at least temporarily, the at least one drive signal, wherein the apparatus further comprises an activating device adapted to selectively activate or deactivate the enabling device. In some embodiments, it is thereby possible to flexibly enable or disable (block) driving of the electrical load.

In further exemplary embodiments, the electrical load is, for example, an electrical machine, such as a rotating electrical machine, e.g., a motor and/or generator, or a linear motor or the like.

In further exemplary embodiments, the at least one input signal may be provided by, for example, an external unit such as a controller or microcontroller and transmitted to the apparatus as input signal.

In further exemplary embodiments, it is provided that the activating device is adapted to receive an enable signal and, based on the enable signal, to activate or deactivate the enabling device.

In further exemplary embodiments, the enable signal may be provided by, for example, an external unit or the same external unit, such as the controller or microcontroller, or by a different external unit (e.g., different controller, switch, etc.).

In further exemplary embodiments, it is provided that the activating device generates the enable signal by itself, e.g., in an event-controlled manner, e.g., in a time-controlled manner.

In further exemplary embodiments, it is provided that the activating device is adapted to supply the enabling device with an electrical operating voltage in order to activate the enabling device.

In further exemplary embodiments, it is provided that the activating device is adapted to disconnect the enabling device from an or the electrical operating voltage in order to deactivate the enabling device.

In further exemplary embodiments, it is provided that the activating device is adapted to generate, for example at least temporarily, the electrical operating voltage.

In further exemplary embodiments, it is provided that the activating device is adapted to receive a first voltage as enable signal and to generate the electrical operating voltage based on the first voltage.

In further exemplary embodiments, it is provided that the activating device and/or the enabling device can be supplied with electrical energy via the enable signal, for example exclusively via the enable signal. In this way, the enabling device and/or the activating device can be supplied or powered via the enable signal, so that, for example, no further electrical supply is used for the enabling device and/or the activating device, while at the same time ensuring that the enabling device is deactivated if no electrical energy is supplied by means of the enable signal.

In further exemplary embodiments, it is provided that the enabling device comprises at least one logic circuit.

In further exemplary embodiments, it is provided that the at least one logic circuit comprises at least one inverter (NOT gate).

In further exemplary embodiments, it is provided that the at least one logic circuit comprises at least a first inverter and a second inverter, wherein the at least one input signal can be supplied to the first inverter, wherein an output signal of the first inverter can be supplied to the second inverter, and wherein the enabling device is adapted to output an output signal of the second inverter as the at least one drive signal.

By using inverters, e.g., instead of non-inverting components, it is possible in some embodiments to ensure that correct drive signals, e.g., modulated signals for controlling motor currents, are output only if the logic circuit or the enabling device is working correctly. For example, in some embodiments, short circuits between individual terminals or signals in the area of the logic circuit or enabling device cannot lead to a safety-critical fault due to the exemplary double inversion by means of the first inverter and the second inverter. Rather, in some embodiments, individual faults such as short circuits between individual terminals or signals in the area of the logic circuit or the enabling device can at most result in an irregular drive signal, which generally does not cause driving of the electrical load, e.g., an electric motor.

In further exemplary embodiments, the enabling device is adapted to receive a plurality of, for example three, input signals and, based on the plurality of input signals, to output, for example at least temporarily, a plurality of drive signals. In this way, for example, electrical multiphase loads can be supplied with corresponding drive signals, e.g., signals that can be flexibly enabled and/or disabled (blocked).

In further exemplary embodiments, it is provided that the at least one input signal is a logic signal or a binary signal, for example a pulse width modulated signal.

Further exemplary embodiments relate to an apparatus for processing at least one input signal, comprising a first apparatus according to the embodiments and a second apparatus according to the embodiments, wherein the at least one input signal can be supplied to the enabling device of the first apparatus, wherein the enabling device of the first apparatus is adapted to output, based on the at least one input signal, for example at least temporarily, at least one first signal to the enabling device of the second apparatus, and wherein the enabling device of the second apparatus is adapted to output, based on the at least one first signal, for example at least temporarily, at least one second signal as the at least one drive signal.

Further exemplary embodiments relate to a method for providing at least one drive signal for an electrical load, comprising: receiving at least one input signal by means of an enabling device, and outputting, based on the at least one input signal, for example at least temporarily, the at least one drive signal by means of the enabling device, wherein the enabling device is selectively activated or deactivated by means of an activating device.

In further exemplary embodiments, it is provided that the method comprises: receiving an enable signal by means of the activating device and, based on the enable signal, activating or deactivating the enabling device.

In further exemplary embodiments, it is provided that the activating device supplies the enabling device with an electrical operating voltage in order to activate the enabling device.

In further exemplary embodiments, it is provided that the activating device disconnects the enabling device from an or the electrical operating voltage in order to deactivate the enabling device.

In further exemplary embodiments, it is provided that the activating device generates, for example at least temporarily, the electrical operating voltage.

In further exemplary embodiments, it is provided that the activating device receives a first voltage as an enable signal and generates the electrical operating voltage based on the first voltage.

In further exemplary embodiments, it is provided that the activating device and/or the enabling device is supplied with electrical energy via the enable signal, for example exclusively via the enable signal.

In further exemplary embodiments, it is provided that the enabling device comprises at least one logic circuit, wherein, for example, the at least one logic circuit comprises at least one inverter.

In further exemplary embodiments, it is provided that the at least one logic circuit comprises at least a first inverter and a second inverter, wherein the at least one input signal is supplied to the first inverter, wherein an output signal of the first inverter is supplied to the second inverter, and wherein the enabling device outputs an output signal of the second inverter as the at least one drive signal.

In further exemplary embodiments, it is provided that the enabling device receives a plurality of, for example three, input signals and, based on the plurality of input signals, outputs, for example at least temporarily, a plurality of drive signals.

In further exemplary embodiments, it is provided that the at least one input signal is a logic signal or a binary signal, for example a pulse width modulated signal.

Further exemplary embodiments relate to a computer-readable storage device comprising instructions that, when executed by a computer, cause the computer to perform the method according to the embodiments.

Further exemplary embodiments relate to a computer program comprising instructions that, when the program is executed by a computer, cause the computer to perform the method according to the embodiments.

Further exemplary embodiments relate to a data carrier signal that transmits and/or characterizes the computer program according to the embodiments.

Further exemplary embodiments relate to a use of the apparatus according to the embodiments and/or of the method according to the embodiments and/or of the computer-readable storage device according to the embodiments and/or of the computer program according to the embodiments and/or of the data carrier signal according to the embodiments for at least one of the following elements: a) providing at least one drive signal for an electrical load, b) at least temporarily enabling or allowing of driving an electrical load, c) at least temporarily disabling or preventing driving of an electrical load, d) increasing a safety, for example a functional safety, for example during operation of an electrical load, e) ensuring a switch-off function for an electrical load.

Further exemplary embodiments relate to an electrical load comprising at least one apparatus according to the embodiments.

Further features, possible applications and advantages of the invention can be derived from the following description of exemplary embodiments of the invention, which are shown in the drawing figures. Thereby, all described or depicted features form the subject matter of the invention by themselves or in any combination, irrespective of their combination in the claims or the references of the claims, and irrespective of their formulation or depiction in the description or in the drawings.

### BRIEF DESCRIPTION OF THE DRAWINGS

FIG. 1 schematically shows a simplified block diagram of an apparatus according to exemplary embodiments,

FIG. 2 schematically shows a simplified flow diagram of methods according to further exemplary embodiments,

FIG. 3 schematically shows a simplified flow diagram of methods according to further exemplary embodiments,

FIG. 4 schematically shows a simplified flow diagram of methods according to further exemplary embodiments,

FIG. 5 schematically shows a simplified flow diagram of methods according to further exemplary embodiments,

FIG. 6 schematically shows a simplified flow diagram of methods according to further exemplary embodiments,

FIG. 7 schematically shows a simplified block diagram of an apparatus according to further exemplary embodiments,

FIG. 8 schematically shows a simplified block diagram of an apparatus according to further exemplary embodiments,

FIG. 9 schematically shows a simplified flow diagram of methods according to further exemplary embodiments,

FIG. 10 schematically shows a simplified block diagram of an apparatus according to further exemplary embodiments, and

FIG. 11 schematically shows aspects of uses according to further exemplary embodiments.

### DETAILED DESCRIPTION

The word “exemplary” or “embodiment” is used herein to mean “serving as an example, instance, or illustration.” Any implementation or aspect described herein as “exemplary” or as an “embodiment” is not necessarily to be construed as preferred or advantageous over other aspects of the disclosure. Likewise, the term “aspects” does not require that all aspects of the disclosure include the discussed feature, advantage, or mode of operation.

Embodiments will now be described in detail with reference to the accompanying drawings. In the following description, numerous specific details are set forth in order to provide a thorough understanding of the aspects described herein. It will be apparent, however, to one skilled in the art, that these and other aspects may be practiced without some or all of these specific details. In addition, well known steps in a method of a process may be omitted from flow diagrams presented herein in order not to obscure the aspects of the disclosure. Similarly, well known components in a device may be omitted from figures and descriptions thereof presented herein in order not to obscure the aspects of the disclosure.

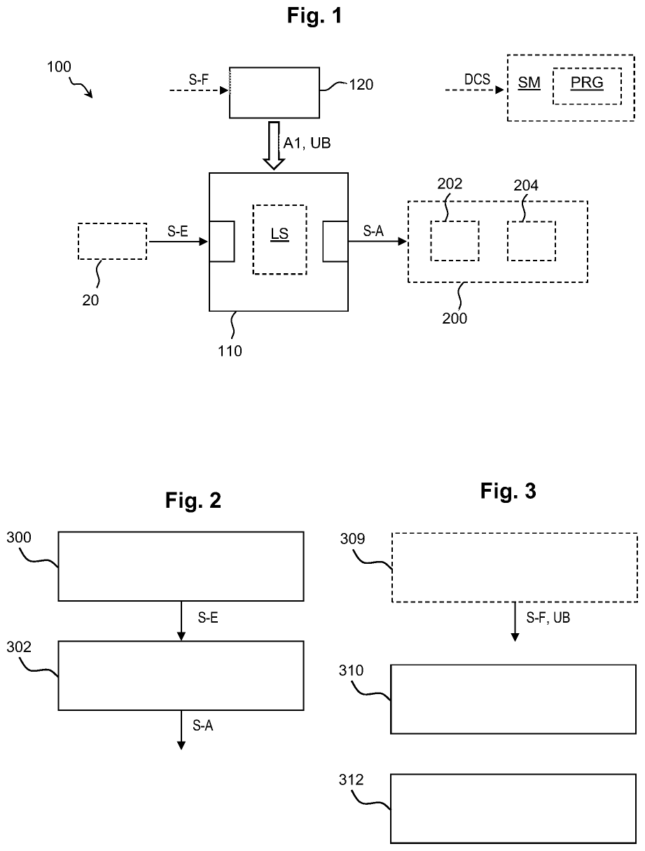

Exemplary embodiments, cf. FIGS. 1 and 2, relate to an apparatus 100 for providing at least one drive signal S-A for an electrical load 200, comprising: an enabling device 110 adapted to receive 300 at least one input signal S-E (FIG. 2) and, based on the at least one input signal S-E, to output 302, for example at least temporarily, the at least one drive signal S-A, wherein apparatus 100 further comprises an activating device 120 adapted to selectively activate enabling device 110, cf. block 310 of FIG. 3, or to deactivate it 312, cf. the block arrow A1 according to FIG. 1. In some embodiments, thus, flexibly enabling or disabling a driving of electrical load 200 can be realized.

In further exemplary embodiments, electrical load 200 is, for example, an electrical machine, such as a rotating electrical machine, e.g., a motor and/or generator, or a linear motor or the like.

By way of example, electrical load 200 may also comprise a power driver stage 202 that can be supplied with the drive signal S-A, and, e.g., at least one component 204 of an electric motor such as one or more stator windings that can be supplied with current by means of the power driver stage 202 based on the drive signal S-A.

In further exemplary embodiments, the at least one input signal S-E may be provided by, for example, an external unit 20 such as a controller or microcontroller and transmitted to apparatus 100 as an input signal.

In further exemplary embodiments, activating device 120 is adapted to receive 309 an enable signal S-F (FIG. 3) and, based on the enable signal S-F, to activate 310 or deactivate 312 the enabling device.

In further exemplary embodiments, the enable signal S-F may be provided by, for example, an external unit or the same external unit 20 such as the controller or microcontroller, or by a different external unit (e.g., different controller, switch, etc.).

In further exemplary embodiments, it is provided that activating device 120 generates the enable signal S-F itself, e.g., event-controlled, e.g., time-controlled.

In further exemplary embodiments, it is provided that activating device 120 is adapted to supply enabling device 110 with an electrical operating voltage UB (FIGS. 1, 3) in order to activate 310 enabling device 110.

In further exemplary embodiments, it is provided that activating device 120 is adapted to disconnect enabling device 110 from an or the electrical operating voltage UB in order to deactivate 312 enabling device 110.

In further exemplary embodiments, it is provided that activating device 120 is adapted to generate, for example at least temporarily, the electrical operating voltage UB.

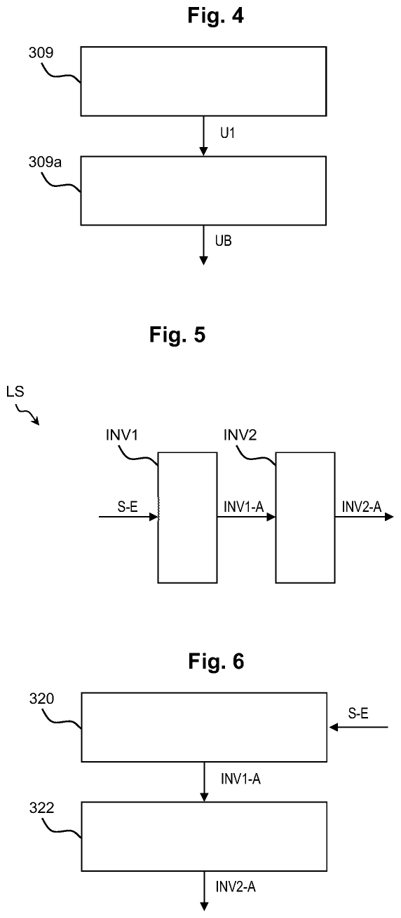

In further exemplary embodiments, FIG. 4, it is provided that activating device 120 is adapted to receive 309 a first voltage U1 (for example 24 volts) as an enable signal S-F and to generate the electrical operating voltage UB (for example 5 Volts or 3.3 Volts or the like) based on the first voltage U1.

In further exemplary embodiments, it is provided that activating device 120 and/or enabling device 110 can be supplied with electrical energy via the enable signal S-F, U1, for example exclusively via the enable signal S-F. As a result, in some embodiments, enabling device 110 and/or activating device 120 can be energized via the enable signal S-F so that, for example, no further electrical supply is used for the enabling device 110 and/or activating device 120, while at the same time ensuring that enabling device 110 is deactivated if no electrical energy is supplied by means of the enable signal S-F. Thus, a safe “switch-off” or blocking of the drive signal S-A can be realized.

In further exemplary embodiments, cf. FIG. 1, it is provided that enabling device 110 comprises at least one logic circuit LS.

In further exemplary embodiments, cf. FIG. 5, it is provided that the at least one logic circuit LS comprises at least one inverter INV1 (NOT gate).

In further exemplary embodiments, it is provided that the at least one logic circuit LS has at least a first inverter INV1 and a second inverter INV2, wherein the at least one input signal S-E can be supplied to first inverter INV1, wherein an output signal INV1-A of first inverter INV1 can be supplied to second inverter INV2, and wherein enabling device 110 is adapted to output an output signal INV2-A of second inverter INV2 as the at least one drive signal S-A.

By using inverters INV1, INV2, e.g., instead of non-inverting components, e.g., logic elements, in some embodiments it is possible to ensure that correct drive signals, e.g., modulated signals for controlling motor currents, are output only if the logic circuit LS or enabling device 110 is working correctly. For example, in some embodiments, short circuits between individual terminals or signals in the area of the logic circuit LS or enabling device 110 cannot lead to a safety-critical fault due to the exemplary double inversion by means of first inverter INV1 and second inverter INV2 (e.g., as long as the faults do not coincidentally also cause a double inversion, e.g., according to FIG. 5, which is comparatively unlikely). Rather, in some embodiments, individual faults such as short circuits between individual terminals or signals in the area of the logic circuit LS or enabling device 110 may at most result in an irregular drive signal S-A, which generally does not cause driving of electrical load 200, such as an electric motor, at least not in the case of those electrical loads 200 which require a specific pattern of the at least one drive signal S-A.

FIG. 6 schematically shows a flow diagram according to further exemplary embodiments. In block 320, first inverter INV1 (FIG. 5) receives the at least one input signal S-E and outputs an inverted signal INV1-A to second inverter INV2, which again inverts the signal INV1-A, cf. block 322. The signal INV2-A may be used as the drive signal S-A in some embodiments.

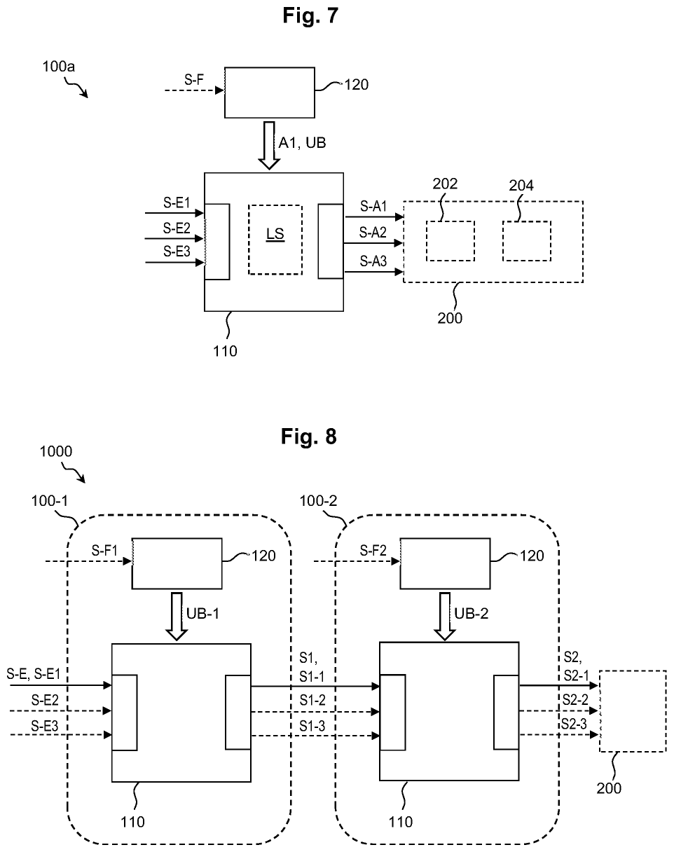

In further exemplary embodiments 100a, cf. FIG. 7, enabling device 110 is adapted to receive a plurality of, for example three, input signals S-E1, S-E2, S-E3 (cf. also block 300 according to FIG. 2) and, based on the plurality of input signals S-E1, S-E2, S-E3, to output, for example at least temporarily, a plurality of drive signals S-A1, S-A2, S-A3. In this way, for example, electrical multiphase loads can be supplied with corresponding drive signals which can be flexibly enabled or disabled, for example.

In further exemplary embodiments, the optional logic circuit LS according to FIG. 7 can, for example, have an inverter arrangement according to FIG. 5 for each of the said exemplary three input signals S-E1, S-E2, S-E3.

In further exemplary embodiments, configurations with two or more than three input signals or drive signals are also conceivable.

In further exemplary embodiments, it is provided that the at least one input signal S-E, S-E1, S-E2, S-E3 is a logic signal or a binary signal, for example a pulse width modulated signal.

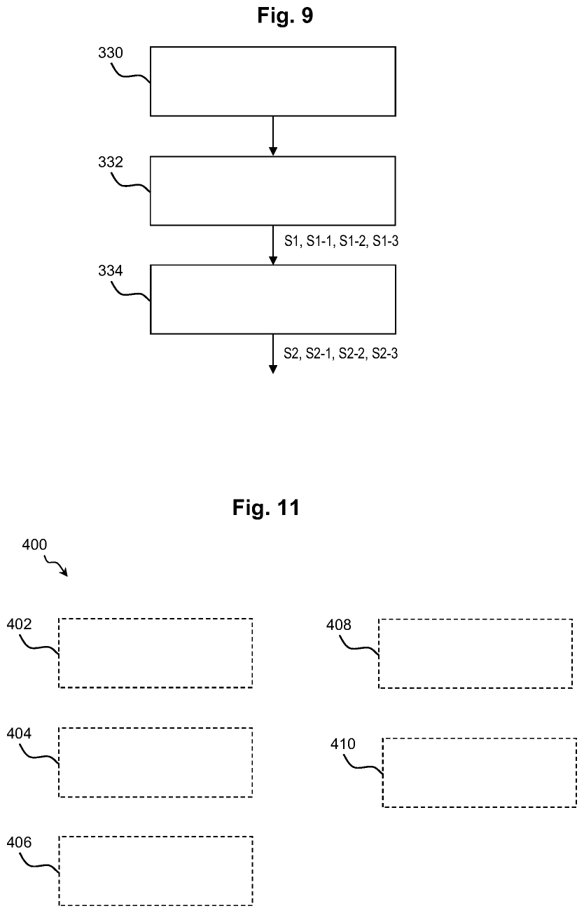

Further exemplary embodiments, cf. FIG. 8, relate to an apparatus 1000 for processing at least one input signal S-E, S-E1, S-E2, S-E3, comprising a first apparatus 100-1 according to the embodiments and a second apparatus 100-2 according to the embodiments, wherein the at least one input signal S-E, S-E1, S-E2, S-E3 can be supplied to enabling device 110 of first apparatus 100-1, wherein enabling device 110 of first apparatus 100-1 is adapted to output 332 (FIG. 9), based on the at least one input signal S-E, S-E1, S-E2, S-E3, for example at least temporarily, at least one first signal S1, S1-1, S1-2, S1-3 to enabling device 110 of second apparatus 100-2, and wherein enabling device 110 of second apparatus 100-2 is adapted to output 334 (FIG. 9), based on the at least one first signal S1, S1-1, S1-2, S1-3, for example at least temporarily, at least one second signal S2, S2-1, S2-2, S2-3 as the at least one drive signal S-A, S-A1, S-A2, S-A3.

In further exemplary embodiments, activating device 120 of first apparatus 100-1 is adapted to receive a first enable signal S-F1 and, based on the first enable signal S-F1, to selectively activate or disable enabling device 110 of first apparatus 100-1. For example, activating device 120 of first apparatus 100-1 may generate from the first enable signal S-F1 a first operating voltage UB-1 for the enabling device 110 of first apparatus 100-1 and control, by means of the first operating voltage UB-1, the selective activating or deactivating of enabling device 110 of first apparatus 100-1.

In further exemplary embodiments, activating device 120 of second apparatus 100-2 is adapted to receive a second enable signal S-F2 and, based on the second enable signal S-F2, selectively activate or disable enabling device 110 of second apparatus 100-2. For example, activating device 120 of second apparatus 100-2 may generate from the second enable signal S-F2 a second operating voltage UB-2 for the enabling device 110 of second apparatus 100-2 and control, by means of the second operating voltage UB-2, the selective activating or deactivating of enabling device 110 of second apparatus 100-2.

In further exemplary embodiments, the enabling devices 110 of the first and second apparatuses 100-1, 100-2 may each comprise a logic circuit LS as described above by way of example with reference to FIGS. 5, 6, 7, for example.

Further exemplary embodiments, cf. FIG. 2, relate to a method for providing at least one drive signal for an electrical load, comprising: receiving 300 at least one input signal S-E by means of an enabling device 110 (FIG. 1), and outputting 302 (FIG. 2), based on the at least one input signal S-E, for example at least temporarily, the at least one drive signal S-A by means of enabling device 110, wherein enabling device 110 is selectively activated 310 (FIG. 3) or deactivated 312 by means of an activating device 120.

In further exemplary embodiments, cf. FIG. 3, it is provided that the method comprises: receiving 309 an enable signal S-F by means of activating device 120 (FIG. 1) and, based on the enable signal S-F, activating 310 or deactivating 312 enabling device 110.

In further exemplary embodiments, it is provided that activating device 120 supplies 309 the enabling device with an electrical operating voltage UB in order to activate 310 enabling device 110.

In further exemplary embodiments, it is provided that activating device 120 disconnects enabling device 110 from an or the electrical operating voltage UB in order to deactivate 312 enabling device 110.

In further exemplary embodiments, it is provided that activating device 120 generates, for example at least temporarily, the electrical operating voltage UB, cf. block 309a according to FIG. 4.

In further exemplary embodiments, it is provided that activating device 120 receives 309 a first voltage U1 (FIG. 4) as enable signal S-F and generates 309a the electrical operating voltage UB based on the first voltage U1.

In further exemplary embodiments, it is provided that activating device 120 and/or enabling device 110 is supplied with electrical energy via the enable signal S-F, for example exclusively via the enable signal S-F.

Further exemplary embodiments, cf. FIG. 1, relate to a computer-readable storage device SM comprising instructions PRG which, when executed by a computer, cause the computer to perform the method according to the embodiments.

Further exemplary embodiments relate to a computer program PRG, comprising instructions that, when executed by a computer, cause the program PRG to perform the method according to the embodiments.

Further exemplary embodiments relate to a data carrier signal DCS that transmits and/or characterizes the computer program PRG according to the embodiments.

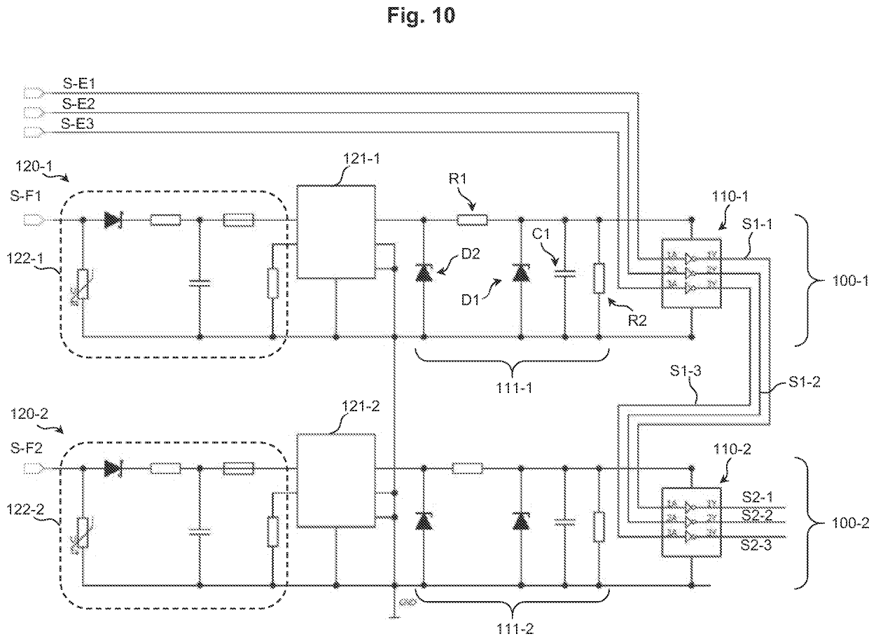

FIG. 10 schematically shows a simplified block diagram of an apparatus according to further exemplary embodiments, which has, for example, a configuration similar to that of apparatus 1000 according to FIG. 8 and can be used in some embodiments, for example, for selectively enabling or disabling input signals S-E1, S-E2, S-E3 or drive signals S2-1, S2-2, S2-3 for an electrical load 200 (FIG. 1) that can be supplied or driven with three phases.

A first enable signal S-F1 can be supplied to an activating device 120-1 of first apparatus 100-1. In some embodiments, an optional input circuit 122-1 is provided for supplying the first enable signal S-F1 to activating device 120-1. In some embodiments, the optional input circuit 122-1 may comprise, for example, at least one of the following elements: a) diode, for example Zener diode, b) resistor, c) fuse, for example microfuse, d) capacitor, e) adjustable resistor.

In some embodiments, activating device 120-1 of first apparatus 100-1 comprises an activating component 121-1, for example implemented as an integrated circuit, which generates an output current for generating an operating voltage for the enabling device 110-1 of first apparatus 100-1 based on a first voltage U1 characterized by the first enable signal S-F1 (see also FIG. 4). Optionally, first apparatus 100-1 may include a further circuit 111-1 that transforms the output current of the enabling component 121-1 into the operating voltage for the enabling device 110-1 of first apparatus 100-1.

In some embodiments, the further circuit 111-1 may comprise, for example, one or more diodes, e.g., Zener diodes D1, D2, e.g., for voltage limiting, and a voltage divider R1, R2 via which a capacitor C1 can be charged that provides the operating voltage for the enabling device 110-1, for example.

Provided, for example, that the first enable signal S-F1 is supplied to first apparatus 100-1, for example in the form of a sufficiently large first voltage U1 (FIG. 4), the activating component 121-1 generates an output current with which the capacitor C1 is charged via the resistor R1. Once the capacitor C1 is sufficiently charged, it provides the operating voltage UB to enabling device 110-1 of first apparatus 100-1, thereby activating enabling device 110-1.

Provided, for example, that the first enable signal S-F1 is no longer supplied to first apparatus 100-1, for example by applying a ground potential instead of the first voltage U1 (FIG. 4), the activating component 121-1 no longer generates an output current, and the capacitor C1 discharges through the resistor R2. Once the capacitor C1 is sufficiently discharged, it no longer provides the operating voltage UB to enabling device 110-1 of first apparatus 100-1, thereby deactivating enabling device 110-1.

Enabling device 110-1 may, for example, have an inverter arrangement according to FIG. 5 for, e.g. each of the exemplary three, input signals S-E1, S-E2, S-E3, which outputs the doubly inverted input signals S-E1, S-E2, S-E3 as first signals S1-1, S1-2, S1-3 only if enabling device 110-1 is activated, for example.

By activating 310 or deactivating enabling device 110-1 by means of the first enable signal S-F1, it is thus possible to cause the input signals S-E1, S-E2, S-E3 to be forwarded from first apparatus 100-1 to second apparatus 100-2 (in the form of the first signals S1-1, S1-2, S1-3) to enabling device 110-2 of second apparatus 100-2, for example.

Second apparatus 100-2 has, for example, a function comparable to first apparatus 100-1, so that by means of enabling device 110-2 of second apparatus 100-2, based on the supplied first signals S1-1, S1-2, S1-3, second signals S2-1, S2-2, S2-3 which can be used, for example, as drive signals for electrical load 200 are output only if a second enable signal S-F2 is active (e.g., a voltage corresponding thereto is sufficiently large). Only then, in some embodiments, an enabling component 121-2 of second apparatus 100-2 comparable to enabling component 121-1 of first apparatus 100-1 is activated and can generate an output current based on which an operating voltage for the enabling device 110-2 of second apparatus 100-2 can be generated by means of the further circuit 111-2. As soon as the operating voltage for the enabling device 110-2 of second apparatus 100-2 is applied to the undesignated capacitor of the further circuit 111-2, enabling device 110-2 of second apparatus 100-2 is activated and, based on the supplied first signals S1-1, S1-2, S1-3, can output the second signals S2-1, S2-2, S2-3, which can be used, for example, as drive signals for electrical load 200.

In other words, apparatus 1000 according to FIG. 10 enables activating or enabling of the drive signals S2-1, S2-2, S2-3 based on the input signals S-E1, S-E2, S-E3 only if both enable signals S-F1 and S-F2 are simultaneously active, e.g., correspond to an operating voltage (e.g., first voltage U1 according to FIG. 4) for the respective activating components 121-1, 121-2. As soon as at least one of the two enable signals S-F1 and S-F2 is not (or no longer) active, no activating or enabling of the drive signals S2-1, S2-2, S2-3 is effected by apparatus 1000, thus allowing the safe switch-off of electrical load 200.

Further exemplary embodiments, cf. FIG. 11, relate to a use 400 of apparatus 100, 100a, 1000 according to the embodiments and/or of the method according to the embodiments and/or of the computer-readable storage device according to the embodiments and/or of the computer program according to the embodiments and/or of the data carrier signal according to the embodiments for at least one of the following elements: a) providing 402 at least one drive signal for an electrical load 200, b) at least temporarily enabling 404 and/or allowing driving of an electrical load 200, c) at least temporarily disabling 406 or preventing driving of an electrical load 200, d) increasing 408 a safety, for example a functional safety, for example during operation of an electrical load, e) ensuring 410 a switch-off function for an electrical load.

Further exemplary embodiments relate to an electrical load 200 (FIG. 1) comprising at least one apparatus 100, 100a, 1000 according to the embodiments.

In some embodiments, the principle according to the embodiments may be used to provide a safe switch-off device for electrical or electronic loads 200, 202, 204. In some embodiments, a self-powered apparatus (supply of the component(s) 120, 110 or 121-1, 110-1, 121-2, 110-2, e.g., from the enable signals S-F, S-F1, S-F2), e.g., a multi-channel apparatus (multiple input signals or drive signals), may be provided for switching off drive signals, for example, such as modulation signals in drive systems.

In some embodiments, use of the principle according to the embodiments may be provided in drive systems. In other embodiments, the principle according to the embodiments may be used in other applications, such as control devices, e.g., for safe switch-off of actuators (e.g., in industrial or automotive applications).

In some embodiments, the principle according to the embodiments, e.g., integrated in drive systems, can be used in, but is not limited to: industrial automation, conveyor belts, shuttle systems, lifting systems, machine tools, packaging machines, etc.

In some embodiments, the principle according to the embodiments may be used for safe switch-off of torque (“STO”) of rotating electrical machines, e.g., according to DIN EN 61800-5-2.

In some embodiments, the principle according to the embodiments allows reliable and cost-effective interruption, e.g., of fast drive signals, e.g., in a wide temperature range.

1-29. (canceled)

30. An apparatus for providing at least one drive signal for an electrical load, comprising:
an enabling device adapted to receive at least one input signal and, based on the at least one input signal, to output, at least temporarily, the at least one drive signal; and
an activating device adapted to selectively activate or deactivate the enabling device.

31. The apparatus according to claim 30, wherein the activating device is adapted to receive an enable signal and, based on the enable signal, to activate or deactivate the enabling device.

32. The apparatus according to claim 30, wherein the activating device is adapted to supply the enabling device with an electrical operating voltage in order to activate the enabling device.

33. The apparatus according to claim 30, wherein the activating device is adapted to disconnect the enabling device from an or the electrical operating voltage in order to deactivate the enabling device.

34. The apparatus according to claim 32, wherein the activating device is adapted to generate, at least temporarily, the electrical operating voltage.

35. The apparatus according to claim 34, wherein the activating device is adapted to receive a first voltage as the enable signal and to generate the electrical operating voltage based on the first voltage.

36. The apparatus according to claim 31, wherein at least one of the activating device and the enabling device are supplied with electrical energy via the enable signal.

37. The apparatus according to claim 30, wherein the enabling device comprises at least one logic circuit.

38. The apparatus according to claim 37, wherein the at least one logic circuit comprises at least one inverter.

39. The apparatus according to claim 37, wherein the at least one logic circuit comprises at least a first inverter and a second inverter, wherein the at least one input signal is supplied to the first inverter, wherein an output signal of the first inverter is supplied to the second inverter, and wherein the enabling device is adapted to output an output signal of the second inverter as the at least one drive signal.

40. The apparatus according to claim 30, wherein the enabling device is adapted to receive a plurality of input signals and based on the plurality of input signals, to output, at least temporarily, a plurality of drive signals.

41. The apparatus according to claim 30, wherein the at least one input signal is a logic signal or a binary signal.

42. An apparatus for processing at least one input signal, comprising:
a first apparatus including a first enabling device, wherein the first enabling device is adapted to receive the at least one input signal and, based on the at least one input signal, to output, at least temporarily, at least a one first signal S1; and
a second apparatus including a second enabling device, wherein the second enabling device is adapted to receive at least the one first signal S1 from the first enabling device and output, based on at least the one first signal S1, at least temporarily, at least one second signal S2 as at least one drive signal.

43. A method for providing at least one drive signal for an electrical load, comprising:
receiving at least one input signal by an enabling device; and
outputting, based on the at least one input signal, at least temporarily, the at least one drive signal by the enabling device; and
selectively activating or deactivating the enabling device using an activating device.

44. The method according to claim 43, comprising:
receiving an enable signal from an activating device and, based on the enable signal, activating or deactivating the enabling device.

45. The method according to claim 44, wherein the activating device supplies the enabling device with an electrical operating voltage in order to activate the enabling device, and/or wherein the activating device disconnects the enabling device from the electrical operating voltage in order to deactivate the enabling device.

46. The method according to claim 45, wherein the activating device generates, for example at least temporarily, the electrical operating voltage.

47. The method according to claim 46, wherein the activating device receives a first voltage as the enable signal and generates the electrical operating voltage based on the first voltage.

48. The method according to claim 44, wherein at least one of the activating device and the enabling device is supplied with electrical energy via the enable signal.

49. The method according to claim 43, wherein the enabling device comprises at least one logic circuit, wherein the at least one logic circuit comprises at least a first inverter and a second inverter, wherein the at least one input signal is supplied to the first inverter, wherein an output signal of the first inverter is supplied to the second inverter, and wherein the enabling device outputs an output signal of the second inverter as the at least one drive signal.

50. The method according to claim 43, wherein the enabling device receives a plurality of input signals and based on the plurality of input signals, outputs a plurality of drive signals.

51. A computer-readable storage device (SM), comprising instructions (PRG) which, when executed by a computer, cause the computer to:
selectively activate or deactivate an activating device to supply an enabling device with an electrical operating voltage in order to activate the enabling device; and
selectively activate or deactivate at least one input signal to the enabling device, wherein the enabling device, when activated by the electrical operating voltage, is configured to output, based on the at least one input signal, at least temporarily, at least one drive signal.
